(19) United States
(12) Patent Application Publication
(10) Pub. No.: US 2009/0277494 A1
(43) Pub. Date: Nov. 12, 2009

(54) SOLAR CONCENTRATORS

(75) Inventors: Massimo Mazzer, London (GB); Barry M. Clive, Somerset (GB); Keith W.J. Barnham, London (GB)

Correspondence Address: VAN DYKE, GARDNER, LINN & BURKHART, LLP, SUITE 207, 2851 CHARLEVOIX DRIVE, S.E., GRAND RAPIDS, MI, 49546, US

(73) Assignee: SOLARSTRUCTURE LIMITED, Ipswich (GB)

(21) Appl. No.: 12/090,737

(22) PCT Filed: Oct. 23, 2006
(86) PCT No.: PCT/GB2006/003959

§ 371 Date: Oct. 15, 2008

(30) Foreign Application Priority Data
Oct. 21, 2005 (GB) 0521531.4

(51) Int. Cl. H01L 31/055; H01L 31/052; H01L 31/00

(52) U.S. Cl. 136/246; 136/257; 250/484.4

(57) ABSTRACT

Light collectors for use in building-integrated solar concentrators comprise waveguiding components incorporating spaced-apart light collecting elements arranged to collect light from a plurality of lenses in a lens array and deliver light to solar cells for photovoltaic conversion, where several lenses are coupled to each individual solar cell. The light collecting elements may comprise shaped ends of bulk waveguides to deliver incident solar radiation directly to the solar cells, or luminescent or amplifying material that converts the incident radiation to a secondary light signal that is delivered to the cells. The lenses may be pivotally mounted in a variety of ways to improve solar tracking by avoiding mechanical clashes between lenses and optimising the amount of incident light that is harvested. Filters containing heavy water may be positioned in front of the solar cells to absorb long wavelength light unconvertible by the cells, heat energy being then extractable from the heavy water.

### BACKGROUND OF THE INVENTION

The present invention relates to solar concentrators.

Solar concentrators, for generating electricity from solar power via the photovoltaic effect, have become a viable option not only for large parabolic dishes sited in open areas with a high degree of direct insolation, but also for small and light modules than can be integrated into buildings. This is largely due to advancements in the manufacturing of low cost plastic lenses and to the development of very high efficiency solar photovoltaic cells.

A number of different building-integrated solar concentrators (BISCs) have been proposed by developers around the world. A common denominator is to take advantage of the overall transparency of small dioptric concentrators to incorporate them into transparent architectural envelopes such as windows so as to provide environmentally-friendly electricity alongside a number of other valuable functions and properties.

BISCs can be considered to be highly effective transparent “solar blinds”, which track the sun and shield the interior of a building from direct sunlight (which is harvested for electricity generation) while transmitting a large proportion of valuable diffuse daylight for glare-free illumination. The building is also protected from excessive heating by abating the external heat load caused by exposure to direct sunlight. Thus, BISCs are in effect a more sophisticated version of widely-used automatic solar blinds (such as automated venetian blinds) that comprise shielding elements which track the sun by rotating about a single horizontal or vertical axis.

In the case of BISCs, the moving elements are lenses that track the sun with one or two rotational degrees of freedom to continually focus direct sunlight onto millimetre- to centimetre-sized light collectors where it is partially converted into electricity by high efficiency photovoltaic cells. Arrays or matrices of mechanically-linked lenses are moved by motors and one or more actuators, depending on the number of degrees of freedom. Within the protected environment provided by the two layers of a double-glazed window or a curtain wall, simple and relatively inexpensive mechanical tracking systems can be used compared to those required for large outdoor solar concentrators that are designed to operate under extreme atmospheric conditions caused by wind, sand, hailstorms and large temperature and humidity variations.

A typical BISC generally comprises the following components:
1. an array of light concentrators, typically lenses, to focus and concentrate the incident sunlight;
2. a corresponding array of photovoltaic cells to convert the sunlight to electricity;
3. light collectors such as compound parabolic concentrators to couple the light from each lens to its associated cell (optional; the cell may be mounted directed at the focal point of the lens);
4. lens-moving mechanisms for tracking the sun so that the lenses are optimally positioned to gather the maximum light throughout the day;
5. a sun tracking system to control the lens-moving mechanisms;
6. heat collectors and heat sinks to remove and dissipate unwanted heat energy that is detrimental to photovoltaic cell operation; and
7. a power controller to control overall operation and power output of the BISC.

BISCs including some or all of these components are known, for example from US 2004/0246596, “Design, Building Integration and Performance of a Hybrid Solar Wall Element”, Andreas Fieber, Eurosun 2004 and “Concentrating PVIB”, Jeff Kenna, ETSU S/P2/00345/00/REP. Preferably, each component should be optimised in terms of performance, aesthetics and cost. The present invention, at least in preferred embodiments, seeks to address this.

### SUMMARY OF THE INVENTION

Accordingly, a first aspect of the present invention is directed to a light collector for use in a solar concentrator comprising a plurality of lenses, the light collector comprising: an optical waveguiding component; and a light collecting element configured to receive light from an associated lens and in response to receiving light from a lens to cause light to propagate along the optical waveguiding component to an end of the optical waveguiding component for delivery to a photovoltaic cell. The light collecting element comprises a region of material containing luminescent centres operable to absorb the received light and in response to the absorption to emit luminescence, the luminescence being coupled into the optical waveguiding component for propagation to an end of the optical waveguiding component for delivery to a photovoltaic cell.

The provision of an optical waveguiding component according to the invention makes for simpler wiring connections between cells to extract the current generated by the solar concentrator, improved aesthetics because the cells can be positioned at the edges of the concentrator, and homogenisation of light concentration and propagation, which can reduce heating of the cells that is detrimental to the photovoltaic conversion efficiency.

According to the invention, the incident solar radiation is used to create a further light signal within the waveguiding component that is transmitted to the cell for conversion. Each light collecting element is operable to cause light to propagate along the optical waveguiding component by generating secondary light in response the received light, the secondary light propagating along the optical waveguiding component to an end of the optical waveguiding component. To this end, each light collecting element comprise a region or portion of material containing luminescent centres operable to absorb the received light and in response to the absorption to emit luminescence as the secondary light, the luminescence being coupled into the optical waveguiding component for propagation to an end of the optical waveguiding component. The optical waveguiding component may comprise a single bulk waveguide, and the light collecting elements may comprise regions or portions of material containing luminescent centres and located within the bulk waveguide. Alternatively, the optical waveguiding component may comprise a single bulk waveguide, and the light collecting elements may comprise portions of material containing luminescent centres and located on an outer surface of the bulk waveguide, such as the light collecting elements being located in concavities in the bulk waveguide.

The light collector may comprise two or more light collecting elements arranged at intervals along the optical waveguiding component, each light collecting element configured to receive light from an associated lens and in response to receiving light from a lens to cause light to propagate along the optical waveguiding component to an end of the optical waveguiding component for delivery to a photovoltaic cell.

A light collector of this type allows a photovoltaic or solar cell to be optically linked to more than one lens in a solar concentrator lens array, using waveguiding technology. Thus, the number of cells required for a lens array can be reduced below the one-to-one lens-cell pairing that is commonly used.

The light collecting elements can be configured in a range of ways. In some embodiments, solar radiation harvested by the lenses is coupled directly to a cell. Hence, each light collecting element may be operable to cause light to propagate along the optical waveguiding component by coupling the received light into the optical waveguiding component so that the received light propagates along the optical waveguiding component to an end of the optical waveguiding component.

The optical waveguiding component may comprise two or more individual waveguides, each waveguide having a first end and a second end, the first ends each comprising a light collecting element, and the waveguides arranged such that their first ends are spaced at intervals along the optical waveguiding component and their second ends are adjacent so that each can deliver light to the same photovoltaic cell. The individual waveguides may be bulk waveguides.

Various designs can be implemented to couple the concentrated incident light into the waveguides for efficient propagation to the cell. For example, the first end of each bulk waveguide may be shaped and configured to direct light incident on the first end into the bulk waveguide for propagation to the second end of the bulk waveguide, the first end thus forming a light collecting element. The optical waveguiding component may comprise a light-receiving face through which incident light can pass. In some embodiments, the first end of each bulk waveguide may comprise a light-receiving face through which incident light can pass, and a planar reflective face arranged behind the light-receiving face and at an angle thereto for directing light that passes through the light-receiving face into a core region of the bulk waveguide for propagation to the second end of the bulk waveguide. In alternative embodiments, the first end of each bulk waveguide may comprise a light-receiving face through which incident light can pass, and a reflective face arranged behind the light-receiving face for directing light that passes through the light-receiving face into a core region of the bulk waveguide for propagation to the second end of the bulk waveguide, the light-receiving face being a circular cylindrical surface, the circle having a centre of curvature, and the reflective face being an elliptical cylindrical surface, the ellipse having a first focus coincident with the centre of curvature and a second focus inside the core region of the bulk waveguide. Thus, in embodiments, the optical waveguiding component may comprise a reflective face arranged behind the light-receiving face for directing light that passes through the light-receiving face into a core region of the bulk waveguide.

Alternatively, each light collecting element may comprise an input surface on the first end of the bulk waveguide through which light can pass into a core region of the bulk waveguide, and an elliptical reflector external to the bulk waveguide and having a first focus that, in use, is made coincident with the focal point of the lens associated with the light collecting element, and a second focus substantially on the input surface so as to direct light received by the light collecting element into the bulk waveguide for propagation to the second end of the bulk waveguide.

Each light collecting element may be operable to cause light to propagate along the optical waveguiding component by utilising the received light to optically amplify a light signal propagating along the optical waveguiding component, the amplified light signal propagating along the optical waveguiding component to an end of the optical waveguiding component. This may be implemented such that each light collecting element comprises a region of the optical waveguiding component that is doped with atoms of a rare earth element that can be pumped to an optically excited state in response to the received light, and the optical waveguiding component is configured to receive a light signal from an optical source at a first end of the optical waveguiding component and to propagate the light signal via the doped regions to a second end of the optical waveguiding component, the light signal being optically amplified by the excited rare earth atoms. Further, the doped regions may contain broadband sensitising material operable to enhance excitation of the rare earth atoms by increasing absorption of the received light and transfer of energy from the received light to the rare earth atoms. In such embodiments the optical waveguiding component may again be one or more bulk waveguides, but alternatively the optical waveguiding component comprises one or more optical fibres.

A second aspect of the present invention is directed to a solar concentrator comprising: a plurality of lenses for receiving and concentrating incident solar radiation; one or more light collectors according to the first aspect of the invention, each light collector arranged so that each of its light collecting elements is positioned to receive concentrated solar radiation from one of the lenses; and one or more photovoltaic cells, each light collector having a photovoltaic cell located at at least one of its ends to receive light that has propagated along the optical waveguiding component from the light collecting elements of the light collector. If the one or more light collectors comprise rare earth doped regions for optical amplification, the solar concentrator may further comprise one or more optical sources, each light collector having an optical source located at a first end operable to generate a light signal to be coupled into the optical waveguiding component, and a photovoltaic cell located at a second end to receive the light signal as amplified by the light collecting elements. In this context, or if the light collectors comprise luminescent material, the one or more photovoltaic cells may be configured for efficient operation when receiving incident light within a wavelength range corresponding to the wavelength range of the secondary light or the light signal.

The solar concentrator may further comprise one or more tapered waveguides having a higher refractive index than a refractive index of the optical waveguiding components, each light collector having a tapered waveguide at at least one of its ends to couple light from the optical waveguiding component to the photovoltaic cell.

Also, the plurality of lenses may be arranged in at least one column, the or each column having a corresponding light collector, the corresponding light collector having a light collecting element for each lens in the column. This is an efficient use of light collectors, since only one per lens column is required and a correspondingly small number of photovoltaic cells is required.

In embodiments of the invention a solar concentrator may comprise: a plurality of lenses for receiving and concentrating incident solar radiation; one or more photovoltaic cells; and one or more waveguiding light collectors for receiving concentrated solar radiation from the plurality of lens and, in response to the received radiation, delivering light to the one or more photovoltaic cells, whereby the or each photovoltaic cell is linked by a waveguiding light collector to more than one lens.

The invention extends to a method of generating electricity using the photovoltaic effect, comprising: using a waveguiding light collector as described to link two or more lenses with a photovoltaic cell, such that the waveguiding light collector receives light from the two or more lenses and, in response to the received light, delivers light to the photovoltaic cell for photovoltaic conversion. The waveguiding light collector may comprise an optical waveguiding component; and two or more light collecting elements arranged at intervals along the optical waveguiding component, each light collecting element arranged to receive light from one of the two or more lenses and in response to receiving light from a lens to cause light to propagate along the optical waveguiding component to an end of the optical waveguiding component for delivery to the photovoltaic cell.

According to an invention disclosed herein there is provided a photovoltaic converter comprising: a photovoltaic cell fabricated from semiconductor material having a bandgap energy defining a wavelength edge below which incident radiation is absorbed by the photovoltaic cell for conversion to electricity via the photovoltaic effect; a filter containing heavy water and arranged to intercept radiation incident on the photovoltaic cell so that the heavy water absorbs at least some of any incident radiation having wavelengths above the wavelength edge and transmits at least some of any incident radiation having wavelengths below the wavelength edge to the photovoltaic cell; and a heat extraction system operable to extract heat energy from the heavy water arising from absorbed incident radiation.

The use of a heavy water filter in conjunction with a photovoltaic cell allows usable energy to be extracted in the form of heat energy from those parts of the incident radiation lying beyond the long wavelength limit of the cell. Thus, the overall power producing efficiency of the cell is increased. The absorption spectrum of heavy water is such that the filter can transmit photons up to about 1.8 μum, thus making a wide spectral range in the infrared available for photovoltaic conversion while at the same time extracting heat energy from longer parts of the spectral range that cannot easily be converted by photovoltaic cells.

For conversion of infrared radiation, at least some of the semiconductor material may have a bandgap energy lower than the bandgap energy of silicon. Silicon converts wavelengths up to about 1.1 μm, and heavy water absorbs greatly above about 1.8 μm, so lower bandgap materials allow all or part of the intervening spectral region to be converted to electrical current by the cell. For example, at least some of the semiconductor material may be germanium, which can convert wavelengths up to about 1.8 μm and is hence well-matched to the properties of a heavy water filter.

In some embodiments, the heat extraction system may comprise a heat exchanger through which a heat exchange fluid is circulated to absorb heat energy from the heavy water. To further increase the amount of heat extractable from the converter, and hence to improve the power efficiency, the converter may further comprise a heat sink for removing heat energy from the photovoltaic cell, wherein the heat extraction system is arranged to circulate heat exchange fluid past the heat sink to absorb heat energy from the heat sink before circulating at least some of the heat exchange fluid through the heat exchanger to absorb heat energy from the heavy water. The heat exchange fluid may be non-heavy (standard) water, thus giving a system suitable for supplying hot water as well as electricity, which is useful in the domestic environment.

The converter may further comprise a thermal source operable to emit infrared radiation and arranged to direct the radiation onto the filter for absorption and transmission to the photovoltaic cell. This makes good use of the spectral region immediately below 1.8 μm which is transmitted by the heavy water filter, compared to a solar photovoltaic converter for which the solar spectrum is comprised mainly of shorter wavelengths.

The photovoltaic cell may comprise at least one subcell fabricated from the said semiconductor material and at least one subcell fabricated from semiconductor material having a bandgap energy different from the said bandgap energy.

According to an invention disclosed herein there is provided a solar concentrator comprising: a plurality of lenses for receiving and concentrating incident solar radiation; one or more photovoltaic converters as described; and one or more waveguiding light collectors for receiving concentrated solar radiation from the plurality of lenses and, in response to the received radiation, delivering light to the one or more photovoltaic converters, whereby the or each photovoltaic converter is linked by a waveguiding light collector to more than one lens. The one or more photovoltaic converters may share a common heat extraction system operable to extract heat energy from the heavy water of each of the filters of the one or more photovoltaic converters.

### BRIEF DESCRIPTION OF THE DRAWINGS

For a better understanding of the invention and to show how the same may be carried into effect reference is now made by way of example to the accompanying drawings in which:

FIG. 1 shows a perspective view of an example building integrated solar concentrator comprising light collectors according to embodiments of the invention;

FIG. 2 shows a schematic side view of an example light collector;

FIG. 3 shows a schematic side view of an example light collecting element that can be implemented with the light collector of FIG. 2;

FIG. 4 shows a schematic side view of further example light collecting elements that can be implemented with the light collector of FIG. 2;

FIG. 5 shows a schematic side view of a yet further example light collecting element that can be implemented with the light collector of FIG. 2;

FIG. 6 shows a schematic side view of part of a further example light collector;

FIG. 7 shows a schematic side view of part of a still further example light collector;

FIG. 8 shows a perspective view of a yet further example light collector;

FIG. 9 shows a graph comparing spectral emissions and absorptions of various sources and materials;

FIG. 10 shows a schematic representation of a photovoltaic converter comprising a heavy water filter in accordance with an embodiment of the invention;

FIG. 11 shows a schematic representation of the photovoltaic converter of FIG. 10, further comprising a heat exchange system in accordance with a further embodiment;

FIG. 12 shows a schematic representation of the photovoltaic converter of FIG. 11, further comprising a thermal radiation source in accordance with a yet further embodiment;

FIG. 13 shows a schematic representation of the photovoltaic converter of FIG. 12, modified for hybrid solar/thermal use in accordance with a still further embodiment; and

FIGS. 14 and 15 show side and rear views of parts of a solar concentrator including light collectors and photovoltaic converters according to embodiments of the invention.

### DETAILED DESCRIPTION

### Light Collectors

The present inventors have found that an important element of building-integrated solar concentrator (BISC) technology is to aim to deliver the light concentrated by each lens to the solar cells (photovoltaic cells) in such a way that:
the impact of statistical variations of the light collection efficiency due to lens misalignments, aberrations or material deterioration is minimised;
the heat load on the cells as well as the impact of other environmental effects like humidity on the module performance is minimised; and
the impact of the random failure of any photovoltaic device on the long term performance of the system is minimised.

The function of a light collector in a BISC is to couple light from the lenses to the photovoltaic cells. Small spots of highly concentrated solar radiation are to be coupled efficiently with the cell in the presence of several sources of alignment errors like mechanical tolerances, heating-driven shape defects in the lenses, and mounting errors. Thus, a light collector can perform a highly important function for efficient BISC operation, relating at least to the factors listed above. However, it is worth noting that collectors are not always used. Instead, a cell can be located at the focus of a lens to receive the concentrated light directly.

The present invention proposes several embodiments of a light collector that aim to implement the above-listed criteria, thus improving BISC performance.

The light collector comprises an optical waveguiding component that incorporates a plurality of light targets or light collecting elements for receiving concentrated light from lenses in a BISC. The waveguide is arranged behind one or more columns or rows of lenses in a BISC, so that each light target receives light from one lens. On receipt of the light from a lens, the relevant light target causes light to propagate along the waveguide to a solar or photovoltaic cell positioned at an end of the waveguide, so that light is emitted from the waveguide end to be incident on the cell, to produce photovoltaic conversion. The light targets may be such as to cause light to propagate in both directions along the waveguide, so that a photovoltaic cell can be provided at each end of the waveguide. In this manner, sunlight incident on a plurality of lenses is coupled by the light collector to just one or two cells.

Thus, photovoltaic cells are not needed at the focal point of every concentrator lens in the BISC lens array, but only at one or both ends of the waveguide. This avoids the need for extensive electrical wiring to contact and connect solar cells at the focus of every lens, and greatly reduces the need for bypass components to compensate for partial or non-uniform light collection at the focal points, or for the failure of one or more cells in a column. The waveguiding component, which in various embodiments is a single optical fibre, a bundle of optical fibres, or one or more bulk waveguides, acts as a homogenising element to make illumination of the solar cell more uniform, thus reducing “hot spots” and increasing cell illumination. Also, the number of cells required for a given array of lens is greatly reduced, and the waveguides allow the cells to be positioned at the edges of the light collector. These factors give an improved appearance to a BISC and allows more diffuse light to be transmitted to a building interior.

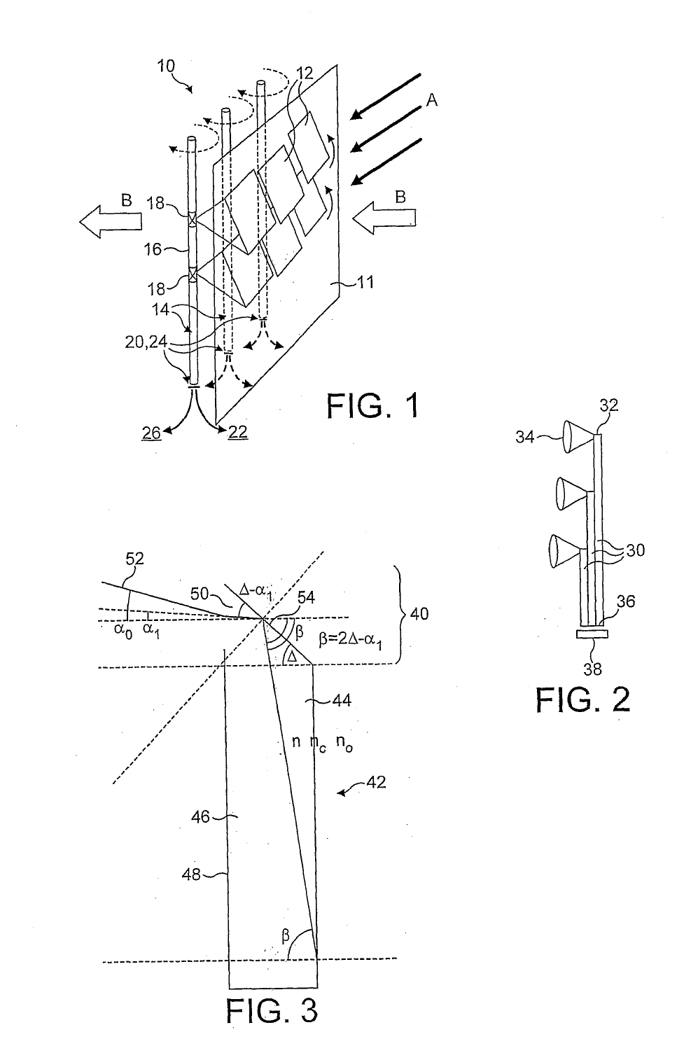

FIG. 1 shows a simplified perspective view of a BISC including a light collector according to an embodiment of the invention. The BISC 10 is arranged behind a front sheet of glass 11 (such as a window) and may be enclosed by a rear sheet of glass (not shown). Lenses 12 are arranged in a regular array, and are movably mounted so as to be pivotable about a horizontal axis to track the sun as its elevation changes throughout the day. A light collector 14 is arranged vertically behind each column of lenses 12 in the array. Each light collector 14 comprises an optical waveguiding component 16 which incorporates a quantity of light targets 18, one light target 18 positioned at the focal point of each lens 12. The waveguiding components 16 are arranged to transmit light in a downwards direction, so that each has a photovoltaic cell 20 positioned at its lower end, to receive light carried by and emitted from the waveguide 16, and convert the received photons to electrical current 22. Each waveguiding component 16 is rotatably mounted together with its associated lens to allow rotation about a vertical axis so that the lenses can track the horizontal movement of the sun. Coupled to each solar cell 20 is a heat sink 24 by which unwanted heat energy 26, which can reduce cell efficiency, can be carried away from the solar cell 20. In operation, both direct sunlight A and diffuse daylight B are incident on the glass sheet 11 and the lenses 12. The diffuse daylight B largely passes through the glass 11 and the BISC 12, while the direct sunlight is captured by the lenses, and concentrated onto the light targets for conversion to electricity by the cells 20.

A number of embodiments of the light collector are proposed. Each exploits the inventive concept of using waveguides to form an optical link between two or more lens and a single photovoltaic cell, thus avoiding drawbacks of the conventional arrangement of one cell per lens. On a basic level, the concept could be embodied by employing a plurality of optical fibres. An optical fibre is positioned behind each lens such that focused light from that lens is coupled into a first end of the fibre. Then, the fibres are collected together in one or more bundles, and each bundle is arranged to deliver light to one photovoltaic cell. Thus, each cell receives light from several lenses. Other embodiments are more complex.

A group of embodiments is based on a waveguiding component that comprises a number of bulk waveguides that are bundled or fused together so that their longitudinal axes are substantially parallel. Each waveguide has a first end positioned to receive light from a lens in a column, so that the first ends are positioned spaced apart from one another. However, the second ends are positioned adjacent to one another, so as to form a common end for the waveguiding component, from which light is delivered to the solar cell. Thus, the bulk waveguides that make up the waveguiding component have different lengths, and are configured in an “organ pipe” arrangement. The embodiments differ in the formation of the first ends of the waveguides, which are shaped and sized to receive the incident concentrated light and direct it efficiently along the waveguide for delivery to the solar cell.

FIG. 2 shows a schematic representation of this organ pipe arrangement, which in this simple example comprises three bulk waveguides 30 of differing lengths positioned next to one another to form a waveguiding component such that their first ends 32 each receive concentrated light from a different lens 34, and their second ends 36 are coincident to emit light onto a single cell 38.

FIG. 3 show a schematic side view of a first end of a bulk waveguide 42 configured in accordance with a first embodiment of the organ pipe arrangement, which uses a wedge at the end of the waveguide 42 to form the light collecting element 40. The waveguide 42 comprises a bulk glass waveguide 44 having a core region 46 and an outer cladding 48 to contain a propagating optical mode inside the waveguide, in accordance with known waveguiding principles. An area on the upper front surface of the waveguide 42 is free from cladding, to form a light-receiving face 50 through which incident concentrated solar light 52 from a lens can pass into the core region 46. The top surface of the waveguide 42 is a surface that slopes downwards from front to back of the waveguide 42, and which is made internally reflective to the solar radiation 52 (by coating, polishing, etc.) to form a reflective face 54 behind the light-receiving face 50. Thus, light 52 entering the waveguide 42 via the light-receiving face 50 reflects from the reflective face 54 and, by virtue of the angle of the reflective face 54, is directed down into the main part of the core region 46 of the waveguide 42, for propagation to the far end of the waveguide 42 where the solar cell is located. The light collecting element 40 and waveguide 42 therefore function somewhat like a periscope.

The refractive indices of the cladding 48 (n_{c}) and the core region 46 (n) may be chosen together with the angle Δ made by the reflective surface relative to the plane orthogonal to the longitudinal axis of the waveguide to optimise the amount of light that can be gathered and directed to the far end of the waveguide. An incident ray 52 is directed as required if it has an angle of incidence α₀ (the angle between the ray and the normal to the light receiving face 50) that gives an angle α₁ between the ray and the normal inside the waveguide after refraction at the surface of the light receiving face 50 that satisfies the condition 2Δ−π+β_{c}<α₁<2Δ−β_{c}, where β_{c} is the critical angle for total internal reflection at the vertical surfaces of the waveguide (the sides of the waveguide substantially parallel to the longitudinal axis). This condition will hold for a range of values of α, depending on the selected values of Δ and the refractive indices, so the waveguide can be optimised for collection of light over a range of altitude angles, as the sun moves throughout the day. A useful range of altitude angles is from −20 to +80 degrees, although other ranges may be give adequate efficiency from the solar cell.

The wedge embodiment of FIG. 3 is primarily effective for directing received light in a downward direction. If the light collector is intended for a large number of lenses, a bulky waveguiding component can result, in which a correspondingly large number of individual bulk waveguides are bundled together. Alternative embodiments are proposed to address this issue, in which differently shaped light collecting elements are used to direct light either up or down, so that lenses in an upper half of a column of lenses can have one waveguiding component and lenses in the lower half of the column can have another waveguiding component (although a whole column could also have a single waveguiding component comprising all upwardly directing light collecting elements or all downwardly directing light collecting elements).

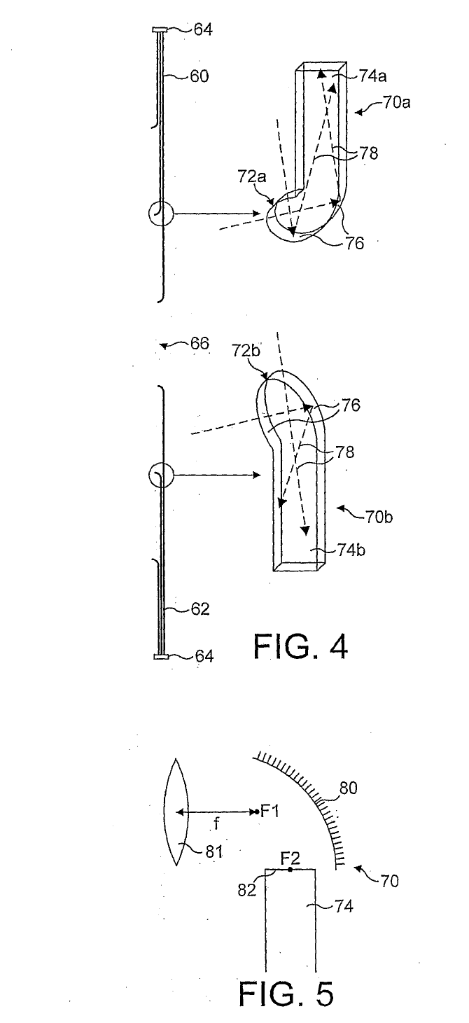

FIG. 4 shows a schematic representation of light collectors according to this further organ pipe embodiment. On the left of the Figure are shown an upper waveguiding component 60 and a lower waveguiding component 62, each with three bulk waveguides in an organ pipe configuration. Each waveguiding component 60, 62 can thus receive light from three lenses (not shown) positioned to focus light onto shaped ends of the waveguides that form the light collecting elements. Other examples can include more or less than three bulk waveguides, with corresponding numbers of lenses. The waveguides are bulk waveguides, for example made from glass. Also, each waveguiding component 60, 62 has a photovoltaic cell 64 arranged at its second end, opposite to the light collecting elements. The waveguiding components 60, 62 are both mounted on a common tie bar 66 that holds them in position relative to the focal points of the lenses, and also provides rotational movement around a common pivot axis with the lens column.

Also shown in FIG. 4 is a close-up view of a light collecting element 70a of the upper waveguiding component 60 and a close-up view of a light collecting element 70b of the lower waveguiding component 62. In this example, the two light collecting elements are slightly differently shaped to allow them to collect and direct incident light in an upward or downward direction respectively. However, other examples may use more similarly or identically shaped light collecting elements both for upward and for downward collection, although the light-collecting efficiency of each will be less optimised than for differently shaped elements. Each element 70a, 70b comprises a transparent front surface 72 directed towards the incident light and having a curved cylindrical shape (where the longitudinal axis of the cylinder is substantially orthogonal to the longitudinal axis of the waveguide 74). This surface 72 acts as a light-receiving face 72 through which light passes to the inside of the waveguide 74. To achieve good light collection, the cylindrical surface may be shaped and positioned to collect light coming from a wide range of incident angles in a vertical plane, to cover a wide range of solar altitudes (such as −20 to +80 degrees, for example). A range of acceptance angles in the horizontal plane is also useful, but can be much smaller than in the vertical plane (such as −20 to +20 degrees, for example) if the tie bar 66 and lens column is rotatable about the vertical axis for the purpose of tracking the sun. The rear surface 76 of the light collecting element 70 is treated to provide a reflective surface 76 behind the light receiving face 72 that is positioned to receive light input through the light receiving face 72 and reflect it substantially along the length of the waveguide 74 for propagation to the solar cell 64. The reflective surface 76 is also curved, but has an elliptical shape instead of the circular shape of the front surface 72. The two surfaces 72, 76 are arranged so that the centre of curvature of the cylindrical front surface 72 substantially overlaps one of the foci of the elliptical rear surface 76, while the second focus of the ellipse is positioned inside the main part of the bulk waveguide 74. This gives an efficient collection of sunlight for all or most of the day without any need to change the orientation of the collector 60, 62 with respect to the tie bar 66 on which it is mounted. As can be seen from FIG. 4, the upper and lower light collecting elements 70a, 70b are differently shaped in that the curved end portion comprising the light receiving face 72 and the reflective face 76 is positioned at a greater angle to the longitudinal axis of the waveguide 74 in the upper element 70a than the lower element 70b. This is to best capture the incoming solar radiation, which is largely directed from above. Also shown in FIG. 4 for each of the light collecting elements 70 are two incident light rays 78 towards the extremes of the range of accepted altitude angles of the sun, showing how each is directed along the waveguide 74. In this example, the lower element is angled to its waveguide such that for very large solar elevations, an incoming ray may miss the reflective face 76 altogether, and propagate undeflected through the light receiving face 72 and along the waveguide 74.

FIG. 5 shows a variant of this embodiment, in which the light collecting element 70 differs in that the shaped first end of the waveguide 74 is replaced by an external elliptical reflector 80 such as a mirror. The external reflector 80 is positioned so that the ellipse has a first focus F1 that coincides that the focal point of the associated lens 81, defined by the focal length f, and a second focus F2 on or near an end input surface 82 of the waveguide 74. In this way, light concentrated by the lens 81 is directed by the reflector 80 in such a way that it is coupled into the waveguide 74 for propagation to the solar cell at the far end of the waveguide 74; this is true for a wide range of solar elevations. In this example, in which the end of the waveguide does not require shaping, the waveguide could be an optical fibre or a bulk waveguide.

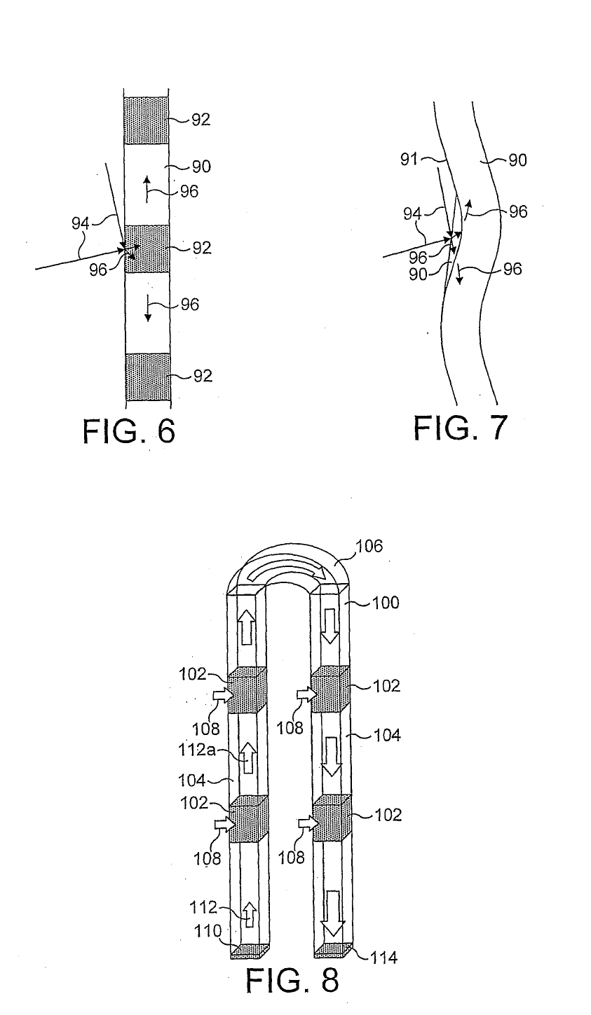

FIG. 6 shows a schematic representation of a further embodiment, in which the organ pipe waveguide arrangement comprising a bundle or group of waveguides is replaced by a waveguiding component that comprises a single waveguide. In this example the waveguide 90 is straight, and has incorporated within it at intervals corresponding to the spacing of the lenses in the concentrator light collecting elements or targets 92 that comprise regions or portions of material containing luminescent material. This emits luminescence 96 in response to absorbed incident light, in this case the concentrated sunlight 94 from the lenses. Thus, sunlight 94 is converted into luminescence 96 that travels along the waveguide 90 for delivery to a solar cell, in contrast to the previous embodiments in which sunlight itself is delivered to the solar cells. The luminescence 96 is emitted in all directions, so it will propagate along the waveguide 90 in both directions. Thus, a solar cell may usefully be provided at each end of the waveguide 90. For efficient absorption of the sunlight 94, the light targets 92 can be optically thick in comparison to the remainder of the waveguide 90. The luminescent material may be based on radiatively effective luminescent centres or concentrators such as quantum dots or dyes dispersed in a transparent matrix, see for example “Thermodynamics of the fluorescent planar concentrator”, E. Yablonovitch, J. Opt. Soc. Am. 70, 1362, (1980) or “Quantum-dot concentrator and thermodynamic model for the global red shift”, K. Barnham, J. L. Marques, J. Hassard and P. O'Brien, Appl. Phys. Lett. 76, 1197 (2000).

This configuration allows a plurality of light collecting elements 92 to be provided within a single waveguide 90, thus offering potential for a less bulky collector than the organ pipe arrangements described previously. However, light targets comprising luminescent materials could be implemented in an organ pipe arrangement if desired, by replacing the shaped waveguide ends with portions containing luminescent material.

The straight waveguide 90 of FIG. 6 containing the absorbing/emitting portions 92 will behave like a planar luminescent concentrator in that the transparent sections of waveguide 90 between the light targets 92 act as ideal (non-interacting) bridges connecting the targets 92 together, so that luminescence from one target 92 travels to other targets 92. As in a standard luminescent concentrator, self-absorption in the targets 92 can thus become a significant factor in limiting the overall light collection efficiency of the light collector, see “Thermodynamics of the fluorescent planar concentrator”, E. Yablonovitch, J. Opt. Soc. Am. 70, 1362, (1980). However, light collection efficiency can be improved by having a sufficiently large Stokes shift between the absorption edge and the luminescence peak of the luminescent material, and by minimising the superposition between the absorption and emission spectra, see “Thermodynamics of the fluorescent planar concentrator”, E. Yablonovitch, J. Opt. Soc. Am. 70, 1362, (1980) or “Quantum dot solar concentrators”, A. J. Chatten, K. W. J. Barnham, B. F Buxton, N. J. Ekins-Daukes and M. A. Malik, Semiconductors, 38, 909 (2004).

FIG. 7 shows a related embodiment that seeks to reduce self-absorption of the luminescence. In this example, the waveguide 90 comprises a number of depressions or concave areas 91 in its surface facing towards the lens, and the luminescent material is provided in portions of material 92 disposed within each concave area 91, which are spaced along the length of the waveguide 90 to correspond to the position of the lenses. Luminescence 96 is generated by the incoming solar radiation 94, and passes from the luminescent material into the main body of the waveguide 90 for propagation to a solar cell. The location of the light targets 92 outside the waveguide 90 allows at least some of the light 96 propagating in the waveguide 90 to avoid the luminescent targets 92, and hence avoid self-absorption. A majority of the concentrated sunlight from the lenses is converted into luminescence, part of which is trapped by the waveguide 90, propagates along both directions in the waveguide, and is then available at the ends of the waveguide for photovoltaic conversion.

To reduce propagation losses, the waveguide may be configured to be of a substantially constant cross-section along its length (as shown in FIG. 7), so that the concave areas 91 can be formed by bends in the waveguide. Also, the luminescent material may be disposed in a lower region of each of the concave areas, with a light receiving surface facing somewhat upwards (again as shown in FIG. 7), so as to better receive the incident sunlight arriving from above.

FIG. 8 shows a schematic representation of a light collector according to a further embodiment. Like the embodiments of FIGS. 6 and 7, this example relies on conversion of the energy in the incident sunlight to produce light for delivery to a solar cell, rather than direct coupling of the sunlight to the cell. However, in this case, the luminescent material is replaced by material that provides optical amplification. Thus, the light collector comprises a waveguiding component 100 within which is incorporated a number of light targets 102, spaced apart so as to correspond to a number of lens. In this case, the waveguiding component is configured to receive sunlight from two columns of lenses, so the waveguiding component comprises two straight arms 104 connected by a curved portion 106 to form a continuous U-shaped waveguide. The light targets 102 comprise regions of the waveguiding component 100 that are doped with atoms of a rare-earth element. Concentrated sunlight 108 incident on the targets 102 is absorbed and “pumps” the rare-earth atoms so that they are transferred to an excited state. An optical source 110 (such as a laser, for example a laser diode) operable to generate a narrow-band light signal is located at a first end of the waveguiding component 100 so that the light signal 112 is coupled into the waveguiding component 100. The light signal 112 propagates to a first light target 102, where it is optically amplified by the excited rare earth material. The amplified signal 112 travels to the next target 102, where it undergoes further amplification, and so on until the amplified signal light arrives at the second end of the waveguiding component 100, where it is delivered to a solar cell 114 for photovoltaic conversion. Thus, the light targets 102 act as optical amplifiers for the propagating signal light 112 through the same nonlinear optical effect exploited in erbium doped fibre amplifiers (EDFAs) used for telecommunications, see “Theoretical investigation of the gain profile of erbium-doped fiber amplifiers”, H. Zech, Optical Fiber Technology, 1, 327 (1995) and “Prediction of gain peak wavelength for Er-doped fiber amplifiers and amplifier chains”, P. F. Wysocki, J. R. Simpson, L. Donghan, Photonics Technology Letters, IEEE 6, 1098 (1994). An optical pumping power from the solar radiation sufficient to generate optical gain of the order of 5 to 7 dB/cm is expected to be of the order of 100 kW/m², which is about 150 suns under standard AM1.5 solar illumination, see “Coefficient determination related to optical gain in erbium-doped silicon-rich silicon oxide waveguide amplifier”, Hak-Seung Han, Se-Young Seo, Jung H. Shin and Namkyoo Park, Appl. Phys. Lett. 81, 3720 (2002).

Any rare earth material can be used to dope the waveguide, such as erbium, ytterbium or thulium. The choice will depend on the wavelength of the light to be amplified, i.e. the light signal generated by the optical source 110. The rare-earth atoms may be doped in combination with broadband sensitisers that act to enhance absorption of the broadband solar radiation, and hence improve the transfer of energy for the optical pumping, see “Strong exciton-erbium coupling in Si nanocrystal-doped SiO₂”, P. G. Kik, M. L. Brongersma and A. Polman, Appl. Phys. Lett. 76, 2325 (2000). This in turn increases the level of amplification that can be achieved, thus making more optical power available to the solar cell for photovoltaic conversion. Examples of sensitisers are quantum dots of silicon or other semiconductor material, see “Broadband sensitizers for erbium-doped planar optical amplifiers: review”, A. Polman and F. C. J. M. van Veggel, J. Opt. Soc. Am. B21, 871 (2004).

The waveguiding component 100 can be formed from one or more bulk waveguides or optical fibres (such as an optical fibre bundle). For more than one fibre or waveguide, each will carry its own light signal, which together are amplified to form an amplified signal for delivery to the solar cell. Also, more than one optical source may be used.

In the latter above-described embodiments involving production of a secondary light signal in response to the absorption of the incident sunlight, the light delivered to the solar cell or cells will likely be narrow-band, compared to the broadband spectrum of solar radiation. This allows the solar cell to be a cell that is optimised for photovoltaic conversion of light in the narrow-band wavelength range. Such cells can offer better conversion efficiency than cells designed for conversion of the solar spectrum.

In all examples, power loss resulting from heat generation in the solar cell, which in the case of broadband solar illumination is caused by the thermalisation of electric carriers to the band-edges of the absorbing material in the cell, instead occurs in the light collectors at each light collecting element, before the light reaches a cell. In these locations, the heat can more easily be disposed of or recycled to produce hot water. This reduces the operating temperature of the cell, which enhances the conversion efficiency.

The various configurations of the optical waveguiding components in the various examples may be combined with the various light collecting elements in combinations other than those described thus far. For example, the single column waveguiding component of FIG. 6 could be used with the optical amplifier light targets of FIG. 8, or the double-column component of FIG. 8 could be used with the luminescent targets of FIG. 6. In either case, triple or higher multiple column waveguiding components could be provided by connecting sufficient linear waveguiding sections with curved sections. Also, the luminescent and amplifying embodiments, in which the propagation of light in the waveguide does not depend on the geometry of incidence, can be utilised to couple rows of lens to a solar cell, instead of columns.

The term “waveguiding component” is intended to cover all combinations of single and multiple waveguides (bundled, adjacent or parallel waveguides), both bulk waveguides and optical fibres.

### Filters For Photovoltaic Cells

Photovoltaic cells used to generate electricity from the sun and other radiation sources via the photovoltaic effect are fabricated from semiconductor material. This has a characteristic bandgap energy. For the generation of electrical current, a photon incident on a cell must have energy at least equal to the bandgap energy so that once absorbed, its energy can transfer an electron from the valence band of the semiconductor to the conduction band to generate an electron-hole pair. Photons with energies below the bandgap energy (longer wavelengths, above the wavelength edge defined by the bandgap energy) cannot do this and so cannot contribute to electricity generation.

However, often the spectrum of radiation incident on a photovoltaic cell contains a proportion of energy at wavelengths longer than the wavelength edge or limit defined by the bandgap energy. This energy is wasted as far as electricity generation is concerned. The present invention proposes an arrangement for converting at least some of this otherwise wasted energy into usable heat energy. In the context of a BISC, the heat energy can be used to heat water used within the building housing the BISC, for example.

The invention relates to using a filter containing heavy water (D₂O) to at least partially absorb any incident radiation having wavelengths above the bandgap limit. The energy of the absorbed photons raises the temperature of the heavy water, and this thermal or heat energy can be extracted from the heavy water and put to use, for example using a heat exchanger. The filter is positioned in front of a photovoltaic cell, and incident photons having wavelengths below the lower absorption edge for heavy water are transmitted by the heavy water filter through to the cell, for conversion into electrical current if they have energies equal to or greater than the bandgap energy. Thus the efficiency of the cell in converting incident radiation into usable energy (electricity plus heat) is increased.

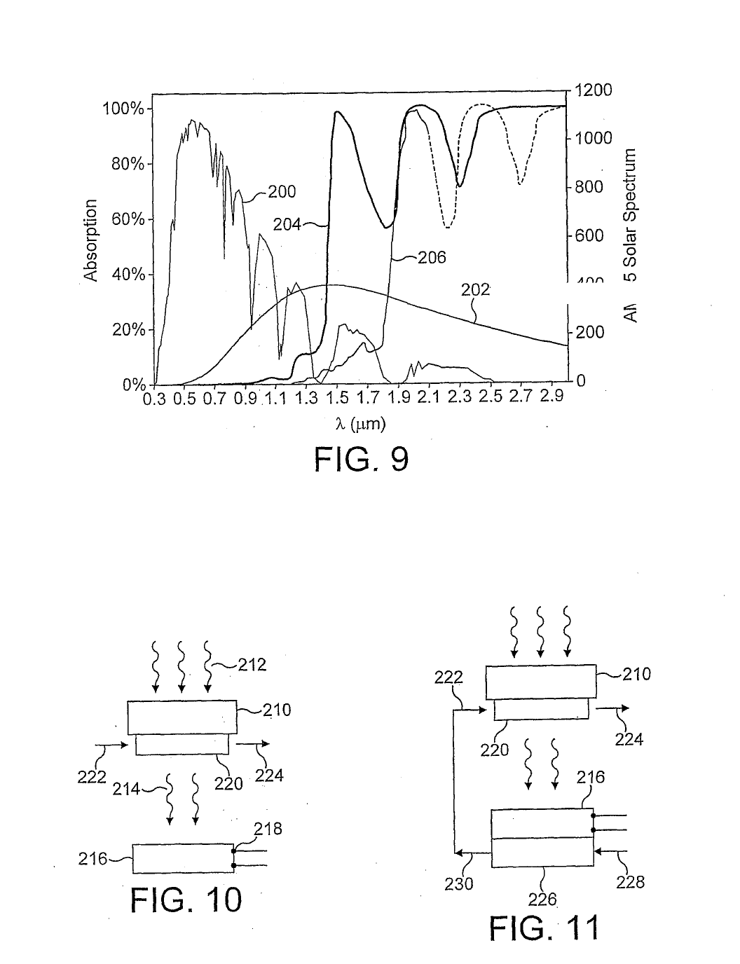

FIG. 9 shows a graph comparing various emission and absorption spectra to illustrate the usefulness of a heavy water filter. Shown in the Figure as functions of wavelength λ are a typical solar spectrum (AM1.5) (line 200), a 2000 K blackbody emission spectrum (line 202), the absorption spectrum of a 1 mm optical thickness of standard water (H₂O) (line 204), and the absorption spectrum of a 1 mm optical thickness of heavy water (line 206).

As can be seen from FIG. 9, heavy water has a low optical absorption up to about 1.8 μm, above which the absorption becomes much greater. If heavy water is used as a filter for a photovoltaic cell receiving solar radiation, for example, the absorption spectrum of the water is such that the filter transmits the bulk of the solar spectrum, lying at wavelengths below 1.8 μm, and absorbs the otherwise wasted longer solar wavelengths for conversion to heat energy.

Silicon photovoltaic cells are often used to convert solar radiation, but the bandgap of silicon is such that it can only convert wavelengths up to about 1.1 μm. This allows a large proportion of the solar spectrum to be converted by a silicon cell, but the longer wavelength light is wasted, including that between 1.1 μm and 1.8 μm that would be transmitted by a heavy water filter. Therefore, heavy water is of particular relevance for photovoltaic cells containing active semiconductor material having smaller bandgap energies than silicon which are hence capable of converting longer wavelength photons. Germanium is such a material; this has a bandgap such that it can absorb and convert photons up to about 1.8 μm. For this reason, germanium is of interest for converting infrared radiation to electricity. In the context of a solar cell or concentrator, germanium allows a greater proportion of the solar spectrum to be converted to electricity than does silicon, since the solar spectrum has a useful fraction of its energy above the 1.1 μm cut-off of silicon. Germanium is also relevant to the photovoltaic conversion of thermal radiation (infrared radiation from a thermal source such as a blackbody or greybody source), which, as shown in FIG. 9, can have the bulk of its energy at wavelengths beyond the silicon cut-off wavelength but with a significant proportion below the germanium cut-off of 1.8 μm. Photons above 1.8 μm can be efficiently absorbed by a heavy water filter for heat production.

It is possible to use standard water (H₂O) as a filter for a photovoltaic cell, instead of heavy water. As is evident from FIG. 9, this arrangement may be applied to the conversion of solar radiation using a silicon photovoltaic cell, see for example “A better solar module performance obtained by employing an infrared water filter”, E. Custodio, L. Acosta, P. J. Sebastian and J. Campos, Solar Energy Materials and Solar Cells 70, 395 (2001). The absorption spectrum of standard water is such that a filter transmits the bulk of the solar spectrum, lying at wavelengths below 1.1 μm which can be converted by silicon, and can absorb the otherwise wasted longer solar wavelengths for conversion to heat energy. However, if one wants to photovoltaically convert photons longer than about 1.4 μm, as comprised in the upper end of the solar spectrum, standard water is of no use, since its optical absorption increases greatly above 1.4 μm and very few photons in this range would be transmitted to the photovoltaic cell. The extension to longer wavelengths of the effective “transmission window” through which photons can be transmitted to a photovoltaic cell by heavy water compared to standard water overcomes this drawback.

A heavy water filter may be simply implemented by arranging the filter in front of a photovoltaic cell to intercept the incident radiation, absorb at least some of the longer wavelength photons, and transmit at least some of the shorter wavelength photons through to the photovoltaic cell for conversion to electricity.

FIG. 10 shows a simplified schematic representation of a photovoltaic converter employing such an arrangement. A heavy water filter 210 receives incoming incident radiation 212 (for example, from the sun). The water in the filter 210 absorbs longer wavelength photons present in the radiation, in particular those photons over 1.8 μm, according to its absorption spectrum (FIG. 9) and transmits the remaining photons 214 to a photovoltaic cell 216. Those transmitted photons having energies above the bandgap of the semiconductor material from which the cell 216 is fabricated are absorbed for the generation of electrical current via the photovoltaic effect within the cell 216. The cell 216, not shown in detail, has electrical contacts 218 by which the current is extracted.

The temperature of the heavy water is raised by conversion of the energy of the absorbed photons to heat energy. This is extracted from the filter 210 using a heat extraction system 220. Any suitable system can be used, depending on the form in which the heat energy is to be employed. For example, the heat extraction system 220 may comprise a heat exchanger, including a pipe or conduit through which a heat exchange fluid is circulated so as to be in thermal contact with the heavy water. Fluid supplied to the heat exchanger (represented by arrow 222) at a lower temperature than the heavy water will absorb heat energy from the heavy water and leave the heat exchanger at a raised temperature (represented by arrow 224), thus carrying the heat energy away from the converter for use elsewhere. The fluid may be air, non-heavy water, or a coolant fluid, for example. Although FIG. 10 shows the heat extraction system 220 positioned between the filter 210 and the cell 216, this is merely for ease of illustration. In practise, the heat extraction system 220 should be arranged such that it interferes as little as possible with transmission of the photons 214 through the filter 210 to the cell 216.

The filter 210 can be implemented in any way that allows adequate transmission of the incident photons 212 to the heavy water and adequate transmission of the unabsorbed photons 214 onwards to the cell 216. For example, the heavy water can be contained in a housing made from quartz glass, which has good transparency in the infrared. The amount of heavy water used, defined in terms of the optical thickness in the propagation direction of the photons, will depend on the level of absorption and heat energy required versus the amount of photons to be passed on for photovoltaic conversion, and the different wavelengths contained in the incident radiation. Optical thicknesses of several millimetres can be suitable, for example, between 1 and 5 millimetres.

The semiconductor material from which the photovoltaic cell is fabricated can be selected according to the spectrum of the incident photons and the relative proportions of that spectrum that are to be absorbed and transmitted by the heavy water. Germanium is particularly useful, in that its wavelength limit for photovoltaic conversion of 1.8 μm matches the absorption edge of the heavy water. No part of an incident spectrum spanning this wavelength (including solar and blackbody radiation) is therefore wasted; those parts above 1.8 μm are harvested for heat generation and those parts below 1.8 μm are harvested for electricity generation. In this context, other materials having bandgaps of lower energy than silicon can be used to achieve photovoltaic conversion beyond the near-infrared wavelengths. Silicon cells may also be employed with a heavy water filter, but any photons lying between about 1.1 μm and 1.8 μm will not be utilised as effectively as for lower bandgap materials.

In use, photovoltaic cells become hot, owing to absorbed photon energy that is not converted by the photovoltaic effect. Raised temperatures reduce the efficiency of the photovoltaic conversion. To address this, the photovoltaic cell can be coupled to a heat sink that moves heat energy away from the cell to keep its temperature down. Any heat sink can perform this function, but in the context of a photovoltaic converter including a heavy water filter, the heat sink can usefully be incorporated with the heat extraction system for the filter, so that the heat energy generated by the cell can be combined with that produced in the filter, and usefully employed.

FIG. 11 shows the photovoltaic converter of FIG. 10 modified in this way, using a heat extraction system in the form of a heat exchange arrangement. The cell 216 is provided with a heat sink 226 that absorbs the undesirable heat energy from the cell 216. Heat exchange fluid 228 is circulated through the heat sink 226 and collects the heat energy therefrom, leaving the heat sink 226 (arrow 230) with an increased temperature. The fluid then enters the heat exchanger 220 coupled to the filter 210, as before (arrow 222), absorbs the heat energy from the heavy water, and leaves with a still further increased temperature (arrow 224). The fluid may be water, for example. If the photovoltaic converter is employed in a domestic environment, the water can be cold water taken from the mains water supply, which is then heated for domestic use by the heat energy produced by both the filter and the cell. In this way, the energy of radiation too long to be converted to electricity is instead utilised to heat water, and undesirable heating of the photovoltaic cell is also used to heat water. The overall efficiency of the cell is improved over what it would be for electricity generation alone, this being further enhanced by the cooling of the cell. In a domestic system, a useful objective is taking mains cold water at 10-20 degrees, heating that water to 35-45 degrees using the heat dissipated by the photovoltaic cell, and then further heating the water to about 60 degrees using the heat from the heavy water filter.

For apparatus utilising solar radiation for electricity generation, there is about 5% of the solar spectrum that lies above the 1.8 μm cut-off wavelength for germanium (see FIG. 9). If a photovoltaic cell containing a germanium junction is used, therefore, this part of the spectrum is lost. A heavy water filter can be used to intercept this radiation and to produce usable heat energy from it. This is a highly efficient way of harvesting this fraction of the solar spectrum.

An alternative to the sun is a thermal source that emits infrared photons, so that the photovoltaic cell generates electrical current by way of the thermophotovoltaic (TPV) effect. A combination of a germanium cell with a heavy water filter is well-suited to this, because of the high proportion of photons up to and beyond 1.8 μm in a thermal spectrum.

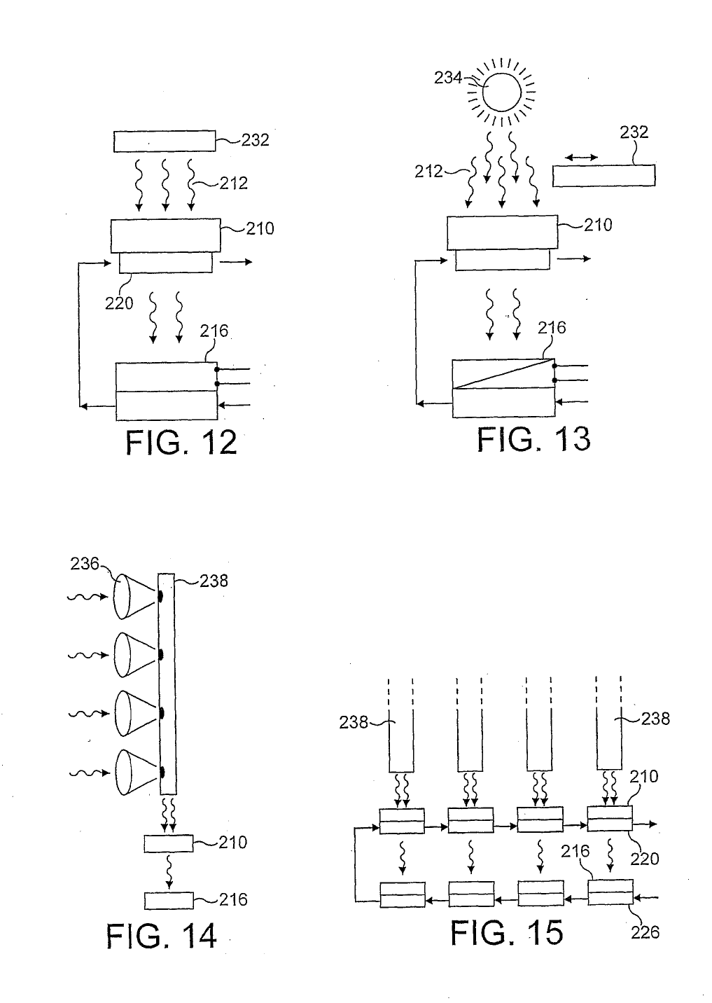

FIG. 12 schematically illustrates a photovoltaic converter similar to that of FIG. 11, but further comprising a thermal source 232 arranged to emit infrared thermal radiation 212 onto the filter 210. The actual specification of the various components of the converter will depend on the spectral characteristics of the thermal source (and vice versa). For example, selective emitters of radiation can be used to tailor the emissivity of a thermal source (operating at about 1200 to 1700 degrees), see “The origin of highly efficient selective emission in rare-earth oxides for thermophotovoltaic applications”, G. Torsello, M. Lomascolo, A. Licciulli, D. Diso, S. Tundo and M. Mazzer, Nature Materials 3, 632-637 (2004), “Porous garnet coatings tailoring the emissivity of thermostructural materials”, A. Liciulli, A. Maffezzoli, D. Diso, M, Mazzer, G. Torsello and S. Tundo, Journal of Sol-Gel Science and Technology 32, 547-251 (2004) or “The challenge of high-performance selective emitters for thermophotovoltaic applications”. A. Licciulli, D. Diso, G. Torsello, S. Tundo, A. Maffezzoli, M. Lomascolo and M. Mazzer, Semiconductor Science and Technology 18, S174-S183 (2003). In particular, the tailoring can be used to reduce the longer wavelength emissions that cannot be absorbed by any thermophotovoltaic cell having a reasonable efficiency (the dark current of a photovoltaic cell increases exponentially with decreasing bandgap energy). Thus, the respective proportions of the thermal spectrum that will be absorbed by the heavy water filter for heat generation (water heating) and absorbed by the cell for electricity generation can be tailored for the power outputs required from a particular system. A typical household in central or northern Europe demands a ratio between electrical and thermal power of about 12%, for example.

A further alternative is a hybrid solar/TPV system arranged to receive solar radiation during daylight hours and thermal radiation from a thermal source at other times. The same cell receives radiation from both sources. To effect this, the converter can be reconfigurable between two arrangements, in one of which the filter 210 is exposed to incident solar radiation, and in the other of which the filter is exposed to incident thermal radiation from a thermal source. This may be achieved by one or more movable components operable to reposition the filter and the cell between positions for receiving the respective radiation types, or for moving the thermal source into and put of alignment with the filter and the cell as required. Alternatively, mirrors and/or lenses could be used to direct radiation from one or other source onto the filter as required.

FIG. 13 shows a schematic representation of the converter of FIG. 12 modified as a hybrid system. In this example, the reconfiguration between the solar and thermal arrangements is achieved by a movable thermal source 232. As illustrated, the thermal source 232 has been moved aside to allow incoming radiation 212 from the sun 234 to arrive at the filter 210. At other times, such as during the night, the thermal source 232 can be moved to the position shown in FIG. 12, where the thermal radiation is incident on the filter 210.

In a further example, the photovoltaic cell can comprise two or more subcells, which can be fabricated from semiconductor materials with different bandgap energies. The different bandgaps can be used to extend the range of wavelengths that can be converted by the cell, which is useful for a broadband radiation source, or to optimise the cell for conversion of photons from two different sources, such as in the hybrid system of FIG. 13. For example, the cell may comprise one or more subcells (each subcell defined by a p-n junction) made from germanium, and one or more subcells made from a semiconductor material with a higher bandgap energy. The germanium junctions are better optimised for conversion of the thermal radiation, while the higher bandgap junctions are better optimised for conversion of the solar radiation. The higher bandgap material may be silicon or gallium arsenide, for example. Other hybrid systems might involve two different thermal sources, with the semiconductor materials selected according to the emission spectra of the sources. The diagonal line dividing the cell in FIG. 13 indicates the possibility of different cell materials in a general way. The subcells may be implemented using a monolithically grown tandem arrangement or a mechanically-made stack, for example.

Photovoltaic converters comprising heavy water filters can be integrated into building integrated solar concentrators (BISCs). For example, they may be used in conjunction with the waveguiding light collectors described in the first part of this application. In summary, these light collectors are waveguiding elements each comprising a number of light receiving elements. Each light receiving element is positioned to receive concentrated light from a lens in an array of lenses, such as in a BISC. By optical coupling and/or converting techniques, the light receiving elements cause light to be propagated along the waveguiding element to a photovoltaic cell at an end of the element. In this way, light from several lenses is coupled to a single cell, allowing fewer cells to be used for a given size of array, and also allowing the cells to be located at the edges of the array, where they do not impinge on the transmission of diffuse light, which is an important property of a BISC. Each of the cells can be provided with a heavy water filter as described above, together with a heat extraction system to obtain heat energy from the heavy water. Conveniently, a single heat extraction system such as the heat exchange arrangement of FIG. 11 can be connected to all the cells and filters.

FIG. 14 shows a side view of a single column of lenses 236 coupled to a filter 210 and a cell 216 by a light collector 238 in the above manner (the converter is shown in simplified form, without no heat extraction system illustrated).

FIG. 15 shows an orthogonal view to FIG. 14, where the lower ends of four light collectors 238 are shown with their associated converters, each comprising a heavy water filter 210 and a cell 216. The heat sinks 226 and heat exchangers 220 of the filters 210 and cells 216 are connected together to allow a single flow of heat exchange fluid to circulate by every heat-producing item, for the collection of heat energy. In a BISC, heated water for use in the building can thereby be obtained.

Arranging the converters in a BISC in this way minimises the number of filters required, and allows the heat generated by the filters to be readily transferred to all or part of the water used to cool the cells. The temperature of the hot water thus produced may be regulated by controlling the flow of the water through the heat sinks, and also adjusting the fraction of that water that is sent to the heat exchangers to extract heat from the heavy water filters. In other words, not all the water needs to be circulated from the heat sinks to the heat exchangers. As mentioned above, the heavy water filters absorb about 5% of the incident solar radiation. In contrast, photovoltaic cells can dissipate about 60-70% of the power they absorb as heat. This means that the temperature rise provided to the circulating water by the heavy water filters could be only about 1 or 2 degrees if all the heat sink water is sent to the heat exchangers. Directing a smaller proportion of water to the heat exchangers may therefore be more beneficial.

In summary, light collectors for use in building-integrated solar concentrators comprise waveguiding components incorporating spaced-apart light collecting elements arranged to collect light from a plurality of lenses in a lens array and deliver light to solar cells for photovoltaic conversion, where several lenses are coupled to each individual solar cell. The light collecting elements may comprise shaped ends of bulk waveguides to deliver incident solar radiation directly to the solar cells, or luminescent or amplifying material that converts the incident radiation to a secondary light signal that is delivered to the cells. The lenses may be pivotally mounted in a variety of ways to improve solar tracking by avoiding mechanical clashes between lenses and optimising the amount of incident light that is harvested. Filters containing heavy water may be positioned in front of the solar cells to absorb long wavelength light unconvertible by the cells, heat energy being then extractable from the heavy water.

1. A light collector for use in a solar concentrator comprising a plurality of lenses, the light collector comprising:
an optical waveguiding component; and
a light collecting element configured to receive light from an associated lens and in response to receiving light from a lens to cause light to propagate along the optical waveguiding component to an end of the optical waveguiding component for delivery to a photovoltaic cell,
wherein the light collecting element comprises a region of material containing luminescent centres operable to absorb the received light and in response to the absorption to emit luminescence, the luminescence being coupled into the optical waveguiding component for propagation to an end of the optical waveguiding component for delivery to a photovoltaic cell.

2. A light collector as claimed in claim 1, comprising two or more light collecting elements arranged at intervals along the optical waveguiding component, each light collecting element configured to receive light from an associated lens and in response to receiving light from a lens to cause light to propagate along the optical waveguiding component to an end of the optical waveguiding component for delivery to a photovoltaic cell.

3. A light collector according to claim 1, in which the optical waveguiding component comprises a light-receiving face through which incident light can pass, and a reflective face arranged behind the light-receiving face for directing light that passes through the light-receiving face into a core region of the optical waveguiding component for propagation to the end of the optical waveguiding component.

4. A light collector according to claim 1, in which the optical waveguiding component comprises a single bulk waveguide, the light collecting element(s) comprising regions of material containing luminescent centres and located within the bulk waveguide.

5. A light collector according to claim 1, in which the luminescent centres are quantum dots or dyes dispersed in a transparent matrix.

6. A light collector according to claim 1, in which the wavelength range of the luminescence is narrow compared to the broadband spectrum of solar radiation.

7. A light collector according to claim 1, in which each light collecting element is operable to cause light to propagate along the optical waveguiding component by utilizing the received light to optically amplify a light signal propagating along the optical waveguiding component, the amplified light signal propagating along the optical waveguiding component to an end of the optical waveguiding component.

8. A light collector according to claim 7, in which each light collecting element comprises a region of the optical waveguiding component that is doped with atoms of a rare earth element that can be pumped to an optically excited state in response to the received light, and the optical waveguiding component is configured to receive a light signal from an optical source at a first end of the optical waveguiding component and to propagate the light signal via the doped regions to a second end of the optical waveguiding component, the light signal being optically amplified by the excited rare earth atoms.

9. A light collector according to claim 8, in which the doped regions contain broadband sensitizing material operable to enhance excitation of the rare earth atoms by increasing absorption of the received light and transfer of energy from the received light to the rare earth atoms.

10. A solar concentrator comprising:
a plurality of lenses for receiving and concentrating incident solar radiation;
one or more light collectors according to any preceding claim, each light collector arranged so that each of its light collecting elements is positioned to receive concentrated solar radiation from one of the lenses; and
one or more photovoltaic cells, each light collector having a photovoltaic cell located at at least one of its ends to receive light that has propagated along the optical waveguiding component from the light collecting elements of the light collector.

11. A solar concentrator according to claim 10, in which the one or more photovoltaic cells are configured for efficient operation when receiving incident light within a wavelength range corresponding to the wavelength range of the luminescence.

12. A photovoltaic converter comprising:
a photovoltaic cell fabricated from semiconductor material having a bandgap energy defining a wavelength edge below which incident radiation is absorbed by the photovoltaic cell for conversion to electricity via the photovoltaic effect;
a filter containing heavy water and arranged to intercept radiation incident on the photovoltaic cell so that the heavy water absorbs at least some of any incident radiation having wavelengths above the wavelength edge and transmits at least some of any incident radiation having wavelengths below the wavelength edge to the photovoltaic cell; and
a heat extraction system operable to extract heat energy from the heavy water arising from absorbed incident radiation.

13. A light collector according to claim 2, in which the optical waveguiding component comprises a light-receiving face through which incident light can pass, and a reflective face arranged behind the light-receiving face for directing light that passes through the light-receiving face into a core region of the optical waveguiding component for propagation to the end of the optical waveguiding component.

14. A light collector according to claim 13, in which the optical waveguiding component comprises a single bulk waveguide, the light collecting element(s) comprising regions of material containing luminescent centres and located within the bulk waveguide.

15. A light collector according to claim 2, in which the optical waveguiding component comprises a single bulk waveguide, the light collecting element(s) comprising regions of material containing luminescent centres and located within the bulk waveguide.

16. A light collector according to claim 2, in which the luminescent centres are quantum dots or dyes dispersed in a transparent matrix.

17. A light collector according to claim 3, in which the luminescent centres are quantum dots or dyes dispersed in a transparent matrix.

18. A light collector according to claim 4, in which the luminescent centres are quantum dots or dyes dispersed in a transparent matrix.

19. A light collector according to claim 5, in which the wavelength range of the luminescence is narrow compared to the broadband spectrum of solar radiation.

20. A light collector according to claim 19, in which each light collecting element is operable to cause light to propagate along the optical waveguiding component by utilizing the received light to optically amplify a light signal propagating along the optical waveguiding component, the amplified light signal propagating along the optical waveguiding component to an end of the optical waveguiding component.
